(19) United States
(12) Patent Application Publication
(10) Pub. No.: US 2014/0232467 A1
(43) Pub. Date: Aug. 21, 2014

(54) HIGH-FREQUENCY AMPLIFIER MODULE AND HIGH-FREQUENCY AMPLIFIER MODULE UNIT

(71) Applicants: Kenji Mukai, Tokyo (JP); Kenichi Horiguchi, Tokyo (JP); Morishige Hieda, Tokyo (JP); Katsuya Kato, Tokyo (JP); Yoshihito Hirano, Tokyo (JP); Kazuya Yamamoto, Tokyo (JP); Hiroyuki Joba, Tokyo (JP); Teruyuki Shimura, Tokyo (JP)

(72) Inventors: Kenji Mukai, Tokyo (JP); Kenichi Horiguchi, Tokyo (JP); Morishige Hieda, Tokyo (JP); Katsuya Kato, Tokyo (JP); Yoshihito Hirano, Tokyo (JP); Kazuya Yamamoto, Tokyo (JP); Hiroyuki Joba, Tokyo (JP); Teruyuki Shimura, Tokyo (JP)

(73) Assignee: Mitsubishi Electric Corporation, Chiyoda-ku (JP)

(21) Appl. No.: 14/237,776

(22) PCT Filed: Aug. 24, 2012
(86) PCT No.: PCT/JP2012/071423

§ 371 Date: Feb. 7, 2014

(30) Foreign Application Priority Data
Oct. 27, 2011 (JP) 2011-236119

(51) Int. Cl. H03F 3/195

(52) U.S. Cl. CPC H03F 3/195; H03F 2200/451; H03F 2200/423; H03F 2200/255
USPC 330/288; 330/295

(57) ABSTRACT

A high-frequency amplifier module includes a driver-stage amplifier 3 that amplifies an RF signal input thereto from an RF input terminal 1, and a final-stage amplifier 5 that amplifies the signal amplified by the driver-stage amplifier 3 and outputs the signal after the amplification to an RF output terminal 7. The driver-stage amplifier 3 is fabricated on a silicon substrate 11, while the final-stage amplifier 5 is fabricated on a gallium arsenide substrate. This configuration downsizes the cost while maintaining a high-frequency characteristic comparable to that in the case where all components of an entire module are fabricated on a gallium arsenide substrate 71.

### TECHNICAL FIELD

The present invention relates, for example, to one or more high-frequency amplifier modules that each amplify a radio frequency (RF) signal, which is a high-frequency signal, and to a high-frequency amplifier module unit in which a plurality of high-frequency amplifier modules are packaged.

### BACKGROUND ART

FIG. 12 is a configuration diagram showing a conventional high-frequency amplifier module disclosed by Non-Patent Document 1 listed below.

In the conventional high-frequency amplifier module, RF signals input from an RF input terminal 101 are amplified by a driver-stage amplifier 102 containing amplifiers arranged in multi-stages. The amplified RF signals may be further amplified by a final-stage amplifier 103, and the further amplified signals are output to an RF output terminal 104.

The conventional high-frequency amplifier module comprises a bypass path 105 in parallel with the final-stage amplifier 103. When the output destination from a changeover switch 107 is switched to the bypass path 105 and a changeover switch 108 is set to an OFF state under the control of a switch control circuit 106, the RF signals amplified by the driver-stage amplifier 102 are output from the RF output terminal 104 via the bypass path 105 without being further amplified by the final-stage amplifier 103.

A Vcc power source 109 supplies a power source voltage to the driver-stage amplifier 102 and the final-stage amplifier 103, and a bias circuit 110 provides a bias to the driver-stage amplifier 102 and the final-stage amplifier 103.

Although it was common to fabricate all components of a high-frequency amplifier module on a silicon substrate, Non-Patent Document 1 teaches a high-frequency amplifier module in which the driver-stage amplifier 102 and the final-stage amplifier 103 are fabricated on a substrate made from gallium arsenide, which is a compound semiconductor having an excellent high frequency characteristic, in order to achieve higher efficiency.

Moreover, the switch control circuit 106 and the bias circuit 110 are also fabricated on the gallium arsenide substrate to meet a requirement on the size of the entire module.

Thus, in the high-frequency amplifier module described in Non-Patent Document 1, all components of the entire module are fabricated on the gallium arsenide substrate.

### PRIOR ART DOCUMENT

### Non Patent Document

Non-Patent Document 1: G. Hau et al., “Multi-Mode WCDMA Power Amplifier Module with Improved Low-Power Efficiency using Stage-Bypass,” IEEE RFIC Symposium Dig., pp. 163-166, June 2010

### SUMMARY OF THE INVENTION

### Problems to be Solved by the Invention

Since the conventional high-frequency amplifier module is constructed as described above, higher efficiency can be achieved. However, since the per-chip cost of a substrate made from gallium arsenide is high, using the conventional high-frequency amplifier module causes a problem of high manufacturing cost.

Embodiments of the present invention address this problem. Accordingly, an object of the embodiments of the present invention is to provide a high-frequency amplifier module and a high-frequency amplifier module unit that reduce the manufacturing cost with a high-frequency characteristic, comparable to that in the conventional art in which all components of an entire module are fabricated on a gallium arsenide substrate, being maintained.

### Means for Solving the Problems

An aspect of the embodiments according to the present invention provides a high-frequency amplifier module, comprising: a silicon substrate; a gallium arsenide substrate; a driver-stage amplifier that includes a plurality of amplifiers arranged in multi-stages and amplifies a signal input from an input terminal; and a final-stage amplifier that further amplifies the amplified signal amplified by the driver-stage amplifier and outputs the further amplified signal to an output terminal, wherein the driver-stage amplifier is fabricated on the silicon substrate, and the final-stage amplifier is fabricated on the gallium arsenide substrate.

According to an aspect of the embodiments of the present invention, since a high-frequency amplifier module comprises a silicon substrate; a gallium arsenide substrate; a driver-stage amplifier that includes a plurality of amplifiers arranged in multi-stages and amplifies a signal input from an input terminal; and a final-stage amplifier that further amplifies the amplified signal amplified by the driver-stage amplifier and outputs the further amplified signal to an output terminal, wherein the driver-stage amplifier is fabricated on the silicon substrate, and the final-stage amplifier is fabricated on the gallium arsenide substrate, cost reduction can be achieved while maintaining a high-frequency characteristic comparable to that in the case where all components of an entire module are fabricated on a gallium arsenide substrate.

### BRIEF DESCRIPTION OF THE DRAWINGS

FIG. 1 is a configuration diagram showing a high-frequency amplifier module according to Embodiment 1 of the present invention;

FIG. 2 is a configuration diagram showing a high-frequency amplifier module according to Embodiment 2 of the present invention;

FIG. 3 is a configuration diagram showing a high-frequency amplifier module according to Embodiment 3 of the present invention;

FIG. 4 is a configuration diagram showing a high-frequency amplifier module according to Embodiment 4 of the present invention;

FIG. 5 is a configuration diagram showing a high-frequency amplifier module according to Embodiment 5 of the present invention;

FIG. 6 is a configuration diagram showing a high-frequency amplifier module according to Embodiment 6 of the present invention;

FIG. 7 is a configuration diagram showing a high-frequency amplifier module unit according to Embodiment 7 of the present invention;

FIG. 8 is a configuration diagram showing a high-frequency amplifier module unit according to Embodiment 8 of the present invention;

FIG. 9 is a configuration diagram showing a high-frequency amplifier module according to Embodiment 9 of the present invention;

FIG. 10 is a configuration diagram showing a high-frequency amplifier module according to Embodiment 10 of the present invention;

FIG. 11 is a configuration diagram showing a high-frequency amplifier module according to Embodiment 11 of the present invention; and

FIG. 12 is a configuration diagram showing a conventional high-frequency amplifier module disclosed in Non-Patent Document 1.

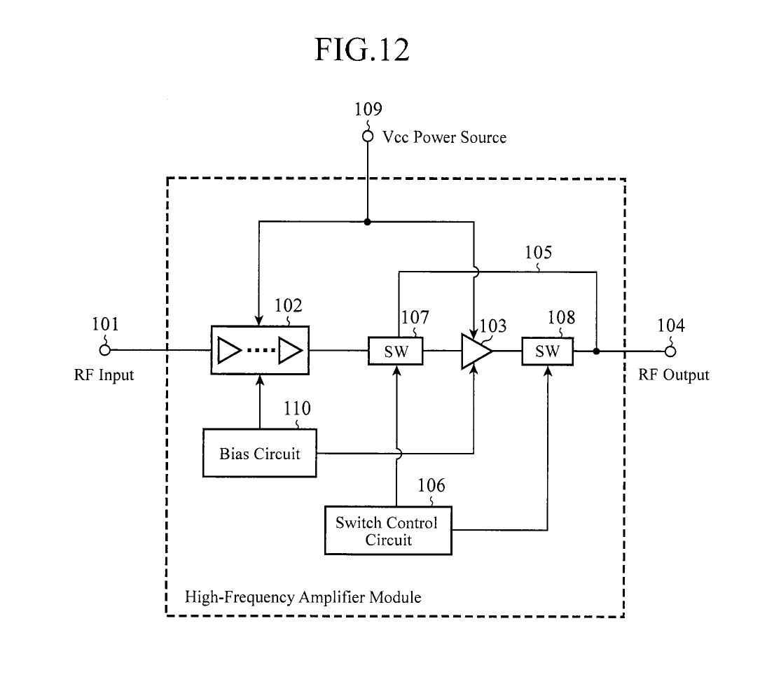

### EMBODIMENTS FOR CARRYING OUT THE INVENTION

Hereinafter, in order to describe the present invention in further detail, embodiments for carrying out the invention will be described with reference to the accompanying drawings. Embodiment 1.

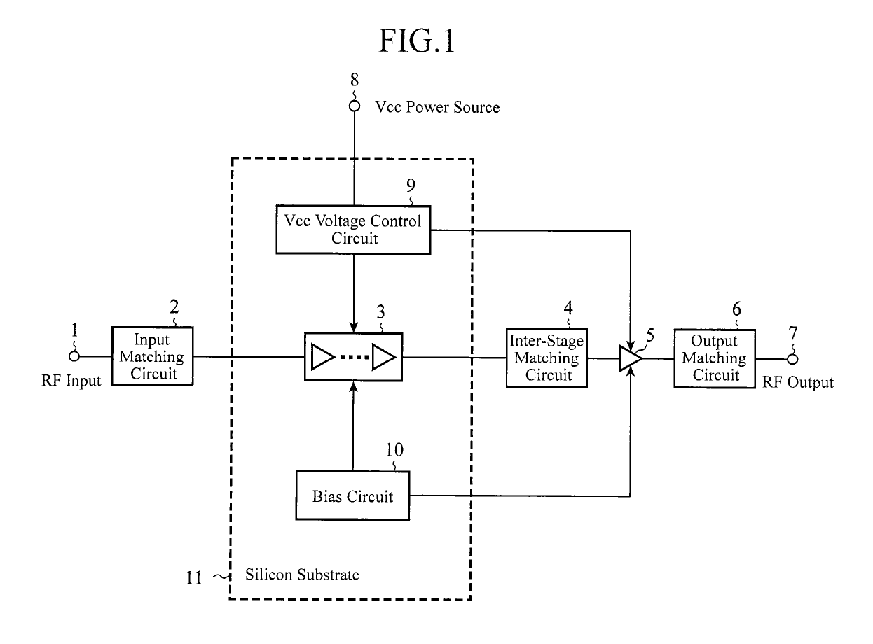

FIG. 1 is a configuration diagram showing a high-frequency amplifier module according to Embodiment 1 of the present invention.

In FIG. 1, an RF input terminal 1 is a terminal to which RF signals are input.

An input matching circuit 2 is a matching circuit that is provided on the input side of a driver-stage amplifier 3.

The driver-stage amplifier 3 is a multistage amplifier including amplifying elements arranged in multiple stages, from the first stage to the N-th stage, and is a device for amplifying RF signals input from the RF input terminal 1 and outputting the amplified RF signals to an inter-stage matching circuit 4.

The inter-stage matching circuit 4 is a matching circuit that is arranged between the driver-stage amplifier 3 and a final-stage amplifier 5.

The final-stage amplifier 5 further amplifies the RF signals amplified by the driver-stage amplifier 3 and outputs the further amplified RF signals to an output matching circuit 6.

The output matching circuit 6 is a matching circuit that is provided on the output side of the final-stage amplifier 5.

The RF output terminal 7 is a terminal that outputs the RF signals amplified by the final-stage amplifier 5.

A Vcc power source 8 is a power source that outputs a power source voltage Vcc.

A Vcc voltage control circuit 9 is a power-source-voltage control circuit that controls a DC voltage to be supplied to a drain or collector of each of the driver-stage amplifier 3 and the final-stage amplifier 5.

Note that a DC voltage supplied to each drain or collector of the driver-stage amplifier 3 and the final-stage amplifier 5 may be the same voltage as the power source voltage Vcc output from the Vcc power source 8 or other voltages modified from the power source voltage Vcc.

In order to set a bias to the driver-stage amplifier 3 and the final-stage amplifier 5, the bias circuit 10 controls a DC voltage or DC current supplied to a gate or base of each of the driver-stage amplifier 3 and the final-stage amplifier 5.

A silicon substrate 11 is a substrate made from silicon, on which the driver-stage amplifier 3, the Vcc voltage control circuit 9, and the bias circuit 10 may be fabricated.

By contrast, the input matching circuit 2, the inter-stage matching circuit 4, the output matching circuit 6, and the final-stage amplifier 5 may be fabricated on a gallium arsenide substrate.

Next, the operation will be described.

First, upon receipt of the power source voltage Vcc supplied from the Vcc power source 8, the Vcc voltage control circuit 9 controls the DC voltage for the drain or collector of each of the driver-stage amplifier 3 and the final-stage amplifier 5 to set the driver-stage amplifier 3 and the final-stage amplifier 5 into a drivable state.

In order to set parameter values, such as an amplification factor of an RF signal in the driver-stage amplifier 3 and the final-stage amplifier 5, to desired values, the bias circuit 10 provides a bias to the driver-stage amplifier 3 and the final-stage amplifier 5 by controlling the DC voltage or DC current supplied to each gate or base of the driver-stage amplifier 3 and the final-stage amplifier 5, for example, in accordance with information about settings of the amplification factor supplied from the outside.

When an RF signal is input from the RF input terminal 1 under a state in which a bias to the driver-stage amplifier 3 and the final-stage amplifier 5 is set by the bias circuit 10, the RF signal is input to the driver-stage amplifier 3 via the input matching circuit 2.

The driver-stage amplifier 3 amplifies the RF signal received from the input matching circuit 2 and outputs the amplified RF signal to the inter-stage matching circuit 4.

The RF signal output from the driver-stage amplifier 3 is input to the final-stage amplifier 5 via the inter-stage matching circuit 4.

The final-stage amplifier 5 further amplifies the RE signal received through the inter-stage matching circuit 4 and outputs the amplified RF signal to the output matching circuit 6.

The RF signal output from the final-stage amplifier 5 goes through the output matching circuit 6 and is output to the outside from the RF output terminal 7.

In the high-frequency amplifier module illustrated in FIG. 1, the driver-stage amplifier 3 is fabricated on the silicon substrate 11, while the final-stage amplifier 5 is fabricated on the gallium arsenide substrate. Amongst the driver-stage amplifier 3 and the final-stage amplifier 5, it is the final-stage amplifier 5 that dominates the high-frequency characteristic of the module; the driver-stage amplifier 3 does not particularly affect the high-frequency characteristic.

Hence, as long as the final-stage amplifier 5 is fabricated on the gallium arsenide substrate having an excellent high-frequency characteristic, the driver-stage amplifier 3 may be fabricated on the silicon substrate 11 with a high-frequency characteristic that is comparable to that in the case where all components of an entire module are fabricated on a gallium arsenide substrate being maintained.

Fabricating the driver-stage amplifier 3 on the silicon substrate 11 in the manner described above allows reducing the area of a chip made from a gallium arsenide substrate, thus decreasing the manufacturing cost.

As described above, in the high-frequency amplifier module according to Embodiment 1, the input matching circuit 2, the inter-stage matching circuit 4, and the output matching circuit 6 are also fabricated on the gallium arsenide substrate. Alternatively, part of these circuits may be fabricated on the silicon substrate 11 or an external module, instead of fabricating all of these circuits on the gallium arsenide substrate. Such an alternative construction also maintains a high-frequency characteristic comparable to that in the case where all components of the entire module are fabricated on the gallium arsenide substrate.

For example, while the output matching circuit 6 is fabricated on the gallium arsenide substrate, the input matching circuit 2 and the inter-stage matching circuit 4 may be fabricated on the silicon substrate 11 or an external module. Also, while the inter-stage matching circuit 4 and the output matching circuit 6 are fabricated on the gallium arsenide substrate, the input matching circuit 2 may be fabricated on the silicon substrate 11 or an external module.

Further, while the input matching circuit 2 and the inter-stage matching circuit 4 are fabricated on the gallium arsenide substrate, the output matching circuit 6 may be fabricated on the silicon substrate 11 or an external module.

In the Embodiment 1 above, the high-frequency amplifier module comprising the input matching circuit 2, the inter-stage matching circuit 4, and the output matching circuit 6 is shown. It is noted that all of the input matching circuit 2, the inter-stage matching circuit 4, and the output matching circuit 6 are optional, and that part or all of these circuits may be eliminated from the high-frequency amplifier module described above.

### Embodiment 2

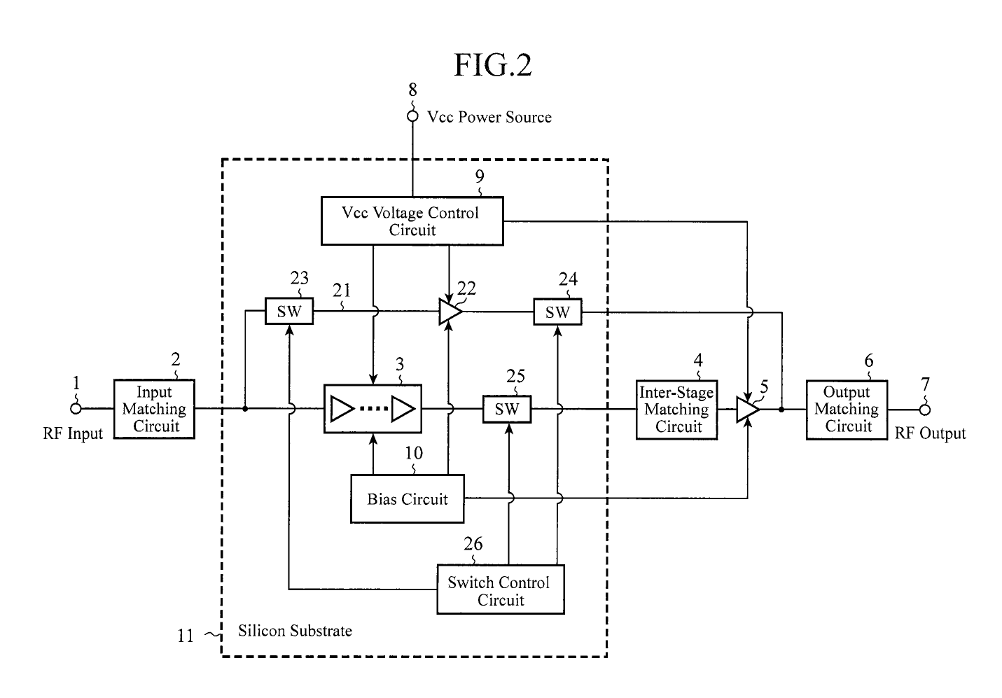

FIG. 2 is a configuration diagram showing a high-frequency amplifier module according to Embodiment 2 of the present invention. In the drawing, the same reference numerals as shown in FIG. 1 denote the same or equivalent parts. Redundant descriptions will be omitted.

A bypass path 21 is a path that has two ends. One end of the two is connected to the input side of the driver-stage amplifier 3, and the other end is connected to the output side of the final-stage amplifier 5.

In Embodiment 2, the path in which the driver-stage amplifier 3 and the final-stage amplifier 5 are arranged is referred to as a “main path.”

A bypass amplifier 22 is a driver-stage amplifier arranged in the bypass path 21. The bypass amplifier 22 is designed to have a size such that the signal amplification factor of the bypass amplifier 22 is smaller than a total of signal amplification factors of the driver-stage amplifier 3 and the final-stage amplifier 5.

A path changeover switch 23 is a switch arranged in the bypass path 21 and on the input side of the bypass amplifier 22. The path changeover switch 23 is turned on or turned off under the control of a switch control circuit 26.

A path changeover switch 24 is a switch arranged in the bypass path 21 and on the output side of the bypass amplifier 22. The path changeover switch 24 is also turned on or turned off under the control of the switch control circuit 26.

A path changeover switch 25 is a switch arranged in the main path and on the output side of the driver-stage amplifier 3. The path changeover switch 25 is also turned ON or turned OFF under the control of the switch control circuit 26.

The switch control circuit 26 is a circuit that turns ON/OFF the path changeover switches 23, 24, and 25 to select the main path or the bypass path 21 as a path that allows the RF signal to flow therethrough.

In Embodiment 2, the bypass amplifier 22, the path changeover switches 23, 24, and 25 and the switch control circuit 26 are fabricated on the silicon substrate 11.

Next, the operation will be described.

First, upon receipt of the power source voltage Vcc supplied from the Vcc power source 8, the Vcc voltage control circuit 9 controls the DC voltage for the drain or collector of each of the driver-stage amplifier 3, the final-stage amplifier 5, and the bypass amplifier 22 to set the driver-stage amplifier 3, the final-stage amplifier 5, and the bypass amplifier 22 into a drivable state.

In order to set parameter values, such as an amplification factor of an RF signal in the driver-stage amplifier 3, the final-stage amplifier 5, and the bypass amplifier 22, to desired values, the bias circuit 10 provides a bias to the driver-stage amplifier 3, the final-stage amplifier 5, and the bypass amplifier 22 by controlling the DC voltage or DC current supplied to each gate or base of the driver-stage amplifier 3, the final-stage amplifier 5, and the bypass amplifier 22, for example, in accordance with information about settings of the amplification factor supplied from the outside.

When an RF signal is input from the RF input terminal 1 under a state in which the bias to the driver-stage amplifier 3, the final-stage amplifier 5, and the bypass amplifier 22 is set by the bias circuit 10, the RF signal goes through the input matching circuit 2.

When the switch control circuit 26 receives, for example, control information directing that the RF signal should be driven with a low output power from the outside, the switch control circuit 26 selects the bypass path 21 as a path for allowing the RF signal to flow by controlling the path changeover switches 23 and 24 to turn on and controlling the path changeover switch 25 to turn off.

As a result, the RF signal that has passed through the input matching circuit 2 is input to the bypass amplifier 22.

The bypass amplifier 22 amplifies the RF signal from the input matching circuit 2 and outputs the amplified RF signal to the output matching circuit 6.

The RE signal output from the bypass amplifier 22 goes through the output matching circuit 6 to be output to the outside from the RF output terminal 7.

When the switch control circuit 26 receives, for example, control information directing that the RF signal should be driven with a high output power from the outside, the switch control circuit 26 selects the main path as a path for allowing the RF signal to flow by controlling the path changeover switches 23 and 24 to turn off and controlling the path changeover switch 25 to turn on.

As a result, the RF signal from the input matching circuit 2 is input to the driver-stage amplifier 3.

The driver-stage amplifier 3 amplifies the RF signal from the input matching circuit 2 and outputs the amplified RF signal to the inter-stage matching circuit 4.

The RE signal output from the driver-stage amplifier 3 passes through the inter-stage matching circuit 4 to be input to the final-stage amplifier 5.

The final-stage amplifier 5 further amplifies the RE signal that has passed through the inter-stage matching circuit 4 and outputs the further amplified RF signal to the output matching circuit 6.

The RF signal output from the final-stage amplifier 5 passes through the output matching circuit 6 to be output to the outside from the RF output terminal 7.

In the high-frequency amplifier module illustrated in FIG. 2, the driver-stage amplifier 3 and the bypass amplifier 22 are fabricated on the silicon substrate 11, and the final-stage amplifier 5 is fabricated on the gallium arsenide substrate. Amongst the driver-stage amplifier 3, the final-stage amplifier 5, and the bypass amplifier 22, it is the final-stage amplifier 5 that dominates the high-frequency characteristic of the module; the driver-stage amplifier 3 and the bypass amplifier 22 do not particularly affect the high-frequency characteristic.

Hence, as long as the final-stage amplifier 5 is fabricated on the gallium arsenide substrate having the excellent high-frequency characteristic, the driver-stage amplifier 3 and the bypass amplifier 22 may be fabricated on the silicon substrate 11 with a high-frequency characteristic comparable to that in the case where all components of the entire module are fabricated on the gallium arsenide substrate being maintained.

Fabricating the driver-stage amplifier 3 and the bypass amplifier 22 on the silicon substrate 11 in the manner described above allows reducing the area of a chip made from a gallium arsenide substrate, thus decreasing the manufacturing cost.

In Embodiment 2, although the path changeover switches 23, 24, and 25 are fabricated on the silicon substrate 11, the path changeover switches 23, 24, and 25 may be fabricated on the gallium arsenide substrate.

In the Embodiment 2 above, the high-frequency amplifier module comprising the input matching circuit 2, the inter-stage matching circuit 4, and the output matching circuit 6 is shown. It is noted that all of the input matching circuit 2, the inter-stage matching circuit 4, and the output matching circuit 6 are optional, and that part or all of these circuits may be eliminated from the high-frequency amplifier module described above.

### Embodiment 3

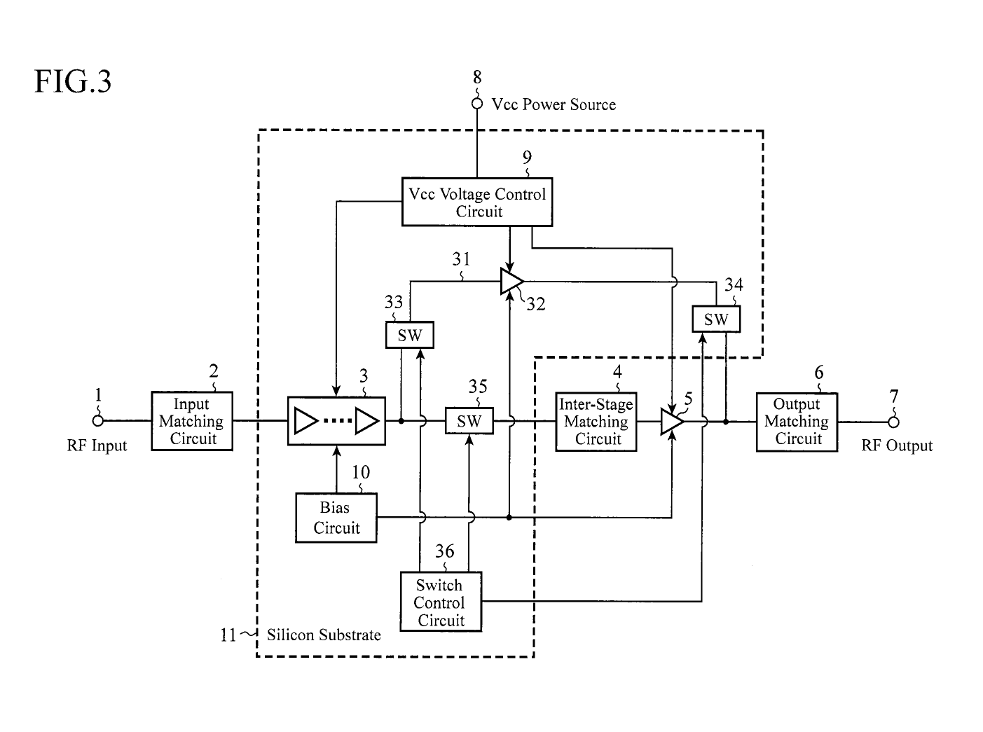

FIG. 3 is a configuration diagram showing a high-frequency amplifier module according to Embodiment 3 of the present invention. In the drawing, the same reference numerals as shown in FIG. 1 denote the same or equivalent parts. Redundant descriptions will be omitted.

A bypass path 31 is a path that has two ends. One end of the two is connected to the output side of the driver-stage amplifier 3, and the other end is connected to the output side of the final-stage amplifier 5.

In Embodiment 3, a path on which the driver-stage amplifier 3 and the final-stage amplifier 5 are arranged is referred to as a “main path.”

A bypass amplifier 32 is a final-stage amplifier arranged in the bypass path 31. The bypass amplifier 32 is designed to have a size smaller than that of the final-stage amplifier 5.

A path changeover switch 33 is a switch arranged in the bypass path 31 and on the input side of the bypass amplifier 32. The path changeover switch 33 is turned on or turned off under the control of a switch control circuit 36.

A path changeover switch 34 is a switch arranged in the bypass path 31 and on the output side of the bypass amplifier 32. The path changeover switch 34 is also turned on or turned off under the control of the switch control circuit 36.

A path changeover switch 35 is a switch arranged in the main path and on the output side of the driver-stage amplifier 3. The path changeover switch 35 is also turned on or turned off under the control of the switch control circuit 36.

The switch control circuit 36 is a circuit that turns ON/OFF the path changeover switches 33, 34, and 35 to select the main path or the bypass path 31 as a path that allows the RF signal to flow therethrough.

In Embodiment 3, the bypass amplifier 32, the path changeover switches 33, 34, and 35, and the switch control circuit 36 are fabricated on the silicon substrate 11.

Next, the operation will be described.

First, upon receipt of the power source voltage Vcc supplied from the Vcc power source 8, the Vcc voltage control circuit 9 controls the DC voltage for the drain or collector of each of the driver-stage amplifier 3, the final-stage amplifier 5, and the bypass amplifier 32 to set the driver-stage amplifier 3, the final-stage amplifier 5, and the bypass amplifier 32 into a drivable state.

In order to set parameter values, such as an amplification factor of an RF signal in the driver-stage amplifier 3, the final-stage amplifier 5, and the bypass amplifier 32, to desired values, the bias circuit 10 provides a bias to the driver-stage amplifier 3, the final-stage amplifier 5, and the bypass amplifier 32 by controlling the DC voltage or DC current supplied to each gate or base of the driver-stage amplifier 3, the final-stage amplifier 5, and the bypass amplifier 32, for example, in accordance with information about settings of the amplification factor supplied from the outside.

When an RF signal is input from the RF input terminal 1 under a state in which the bias to the driver-stage amplifier 3, the final-stage amplifier 5, and the bypass amplifier 32 has been set by the bias circuit 10, the RF signal passes through the input matching circuit 2.

The driver-stage amplifier 3 amplifies the RF signal that has passed through the input matching circuit 2.

When the switch control circuit 36 receives, for example, control information directing that the RF signal should be driven with a low output power from the outside, the switch control circuit 36 selects the bypass path 31 as a path for allowing the RF signal to flow by controlling the path changeover switches 33 and 34 to turn on and controlling the path changeover switch 35 to turn off.

As a result, the RF signal amplified by the driver-stage amplifier 3 is input to the bypass amplifier 32.

The bypass amplifier 32 amplifies the RF signal that has passed through the input matching circuit 2 and outputs the amplified RF signal to the output matching circuit 6.

The RF signal output from the bypass amplifier 32 passes through the output matching circuit 6 to be output to the outside from the RF output terminal 7.

When the switch control circuit 36 receives, for example, control information directing that the RF signal should be driven with a high output power from the outside, the switch control circuit 36 selects the main path as a path for allowing the RF signal to flow by controlling the path changeover switches 33 and 34 to turn off and controlling the path changeover switch 35 to turn on.

As a result, the RF signal amplified by the driver-stage amplifier 3 passes through the inter-stage matching circuit 4 to be input to the final-stage amplifier 5.

The final-stage amplifier 5 amplifies the RF signal that has passed through the inter-stage matching circuit 4 and outputs the amplified RF signal to the output matching circuit 6.

The RF signal output from the final-stage amplifier 5 passes through the output matching circuit 6 to be output to the outside from the RF output terminal 7.

In the high-frequency amplifier module illustrated in FIG. 3, the driver-stage amplifier 3 and the bypass amplifier 32 are fabricated on the silicon substrate 11, and the final-stage amplifier 5 is fabricated on the gallium arsenide substrate. Amongst the driver-stage amplifier 3, the final-stage amplifier 5, and the bypass amplifier 32, it is the final-stage amplifier 5 that dominates the high-frequency characteristic of the module; the driver-stage amplifier 3 and the bypass amplifier 32 do not particularly affect the high-frequency characteristic.

Hence, as long as the final-stage amplifier 5 is fabricated on the gallium arsenide substrate having the excellent high-frequency characteristic, the driver-stage amplifier 3 and the bypass amplifier 32 may be fabricated on the silicon substrate 11 with a high-frequency characteristic comparable to that in the case where all components of the entire module are fabricated on the gallium arsenide substrate being maintained.

Fabricating the driver-stage amplifier 3 and the bypass amplifier 32 on the silicon substrate 11 in the manner described above allows reducing the area of a chip made from a gallium arsenide substrate, thus decreasing the manufacturing cost.

In Embodiment 3, although the path changeover switches 33, 34, and 35 are fabricated on the silicon substrate 11, the path changeover switches 33, 34, and 35 may be fabricated on the gallium arsenide substrate.

In the Embodiment 3 above, the high-frequency amplifier module comprising the input matching circuit 2, the inter-stage matching circuit 4, and the output matching circuit 6 is shown. It is noted that all of the input matching circuit 2, the inter-stage matching circuit 4, and the output matching circuit 6 are optional, and that part or all of these circuits may be eliminated from the high-frequency amplifier module described above.

### Embodiment 4

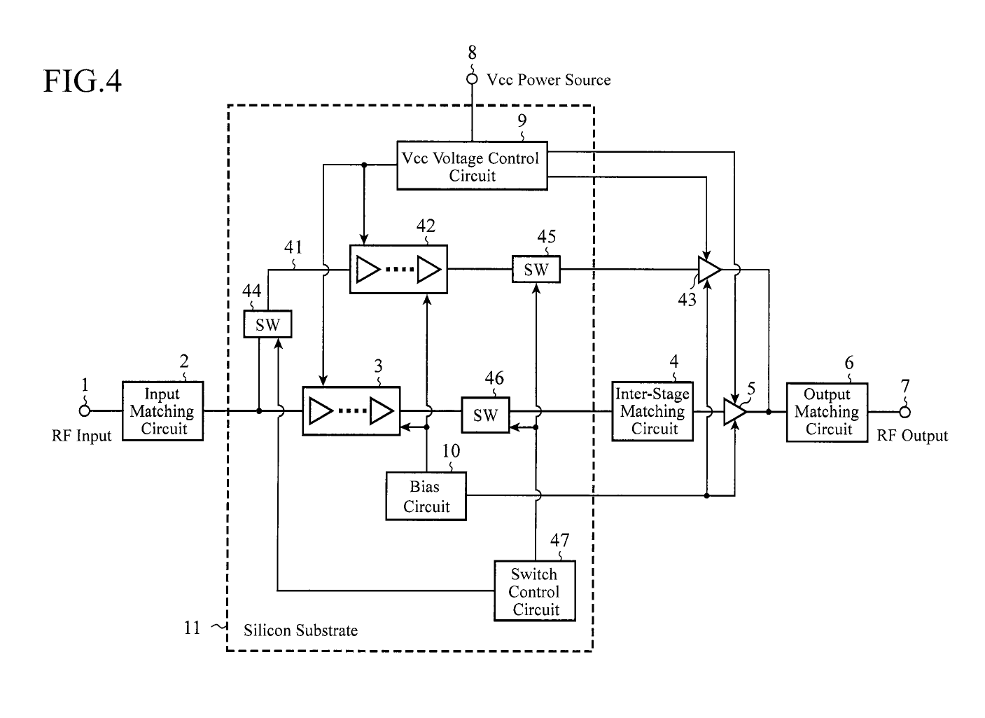

FIG. 4 is a configuration diagram showing a high-frequency amplifier module according to Embodiment 4 of the present invention. In the drawing, the same reference numerals as shown in FIG. 1 denote the same or equivalent parts. Redundant descriptions will be omitted.

A bypass path 41 is a path that has two ends. One end of the two is connected to the input side of the driver-stage amplifier 3, and the other end is connected to the output side of the final-stage amplifier 5.

In Embodiment 4, a path on which the driver-stage amplifier 3 and the final-stage amplifier 5 are arranged is referred to as a “main path.”

A bypass driver-stage amplifier 42 is a multi-stage amplifier arranged in the bypass path 41, and it includes amplifying elements arranged in multiple stages, from the first stage to the N-th stage. The bypass driver-stage amplifier 42 is a device for amplifying RF signals input from the RF input terminal 1.

A bypass final-stage amplifier 43 is a device, arranged in the bypass path 41, for further amplifying the RF signal amplified by the bypass driver-stage amplifier 42 and for outputting the further amplified RF signal to the output matching circuit 6.

Note that the bypass final-stage amplifier 43 is designed to have a size smaller than that of the final-stage amplifier 5.

A path changeover switch 44 is a switch arranged in the bypass path 41 and on the input side of the bypass driver-stage amplifier 42. The path changeover switch 44 is turned on or turned off under the control of a switch control circuit 47.

A path changeover switch 45 is a switch arranged in the bypass path 41 and on the output side of the bypass driver-stage amplifier 42. The path changeover switch 45 is also turned on or turned off under the control of the switch control circuit 47.

A path changeover switch 46 is a switch arranged in the main path and on the output side of the driver-stage amplifier 3. The path changeover switch 46 is also turned on or turned off under the control of the switch control circuit 47.

The switch control circuit 47 turns ON/OFF the path changeover switches 44, 45, and 46 to select the main path or the bypass path 41 as a path that allows the RF signal to flow therethrough.

In Embodiment 4, the bypass driver-stage amplifier 42, the path changeover switches 44, 45, and 46, and the switch control circuit 47 are fabricated on the silicon substrate 11.

The bypass final-stage amplifier 43 is fabricated on the gallium arsenide substrate.

Next, the operation will be described.

First, upon receipt of the power source voltage Vcc supplied from the Vcc power source 8, the Vcc voltage control circuit 9 controls the DC voltage for the drain or collector of each of the driver-stage amplifier 3, the final-stage amplifier 5, the bypass driver-stage amplifier 42, and the bypass final-stage amplifier 43 to set the driver-stage amplifier 3, the final-stage amplifier 5, the bypass driver-stage amplifier 42, and the bypass final-stage amplifier 43 into a drivable state.

In order to set parameter values, such as an amplification factor of the RF signal in the driver-stage amplifier 3, the final-stage amplifier 5, the bypass driver-stage amplifier 42, and the bypass final-stage amplifier 43, to desired values, the bias circuit 10 provides a bias to the driver-stage amplifier 3, the final-stage amplifier 5, the bypass driver-stage amplifier 42, and the bypass final-stage amplifier 43 by controlling the DC voltage or DC current supplied to each gate or base of the driver-stage amplifier 3, the final-stage amplifier 5, the bypass driver-stage amplifier 42, and the bypass final-stage amplifier 43, for example, in accordance with information about settings of the amplification factor supplied from the outside.

When an RF signal is input from the RF input terminal 1 under a state in which the bias to the driver-stage amplifier 3, the final-stage amplifier 5, the bypass driver-stage amplifier 42, and the bypass final-stage amplifier 43 is set by the bias circuit 10, the RF signal passes through the input matching circuit 2.

When the switch control circuit 46 receives, for example, control information directing that the RF signal should be driven with a low output power from the outside, the switch control circuit 46 selects the bypass path 41 as a path for allowing the RF signal to flow by controlling the path changeover switches 44 and 45 to turn on and controlling the path changeover switch 46 to turn off.

As a result, the RF signal that has passed through the input matching circuit 2 is input to the bypass driver-stage amplifier 42.

The bypass driver-stage amplifier 42 amplifies the RF signal that has passed through the input matching circuit 2 and outputs the amplified RF signal to the bypass final-stage amplifier 43.

The bypass final-stage amplifier 43 further amplifies the RF signal amplified by the bypass driver-stage amplifier 42 and outputs the further amplified RF signal to the output matching circuit 6.

The RF signal output from the bypass final-stage amplifier 43 passes through the output matching circuit 6 to be output to the outside from the RF output terminal 7.

When the switch control circuit 47 receives, for example, control information directing that the RF signal should be driven with a high output power from the outside, the switch control circuit 47 selects the main path as a path for allowing the RE′ signal to flow by controlling the path changeover switches 44 and 45 to turn off and controlling the path changeover switch 46 to turn on.

As a result, the RF signal that has passed through the input matching circuit 2 is input to the driver-stage amplifier 3.

The driver-stage amplifier 3 amplifies the RF signal that has passed through the input matching circuit 2 and outputs the amplified RF signal to the inter-stage matching circuit 4.

The RF signal output from the driver-stage amplifier 3 passes through the inter-stage matching circuit 4 to be input to the final-stage amplifier 5.

The final-stage amplifier 5 amplifiers the RF signal that has passed through the inter-stage matching circuit 4 and outputs the amplified RF signal to the output matching circuit 6.

The RF signal output from the final-stage amplifier 5 passes through the output matching circuit 6 to be output to the outside from the RF output terminal 7.

In the high-frequency amplifier module illustrated in FIG. 4, the driver-stage amplifier 3 and the bypass driver-stage amplifier 42 are fabricated on the silicon substrate 11, and the final-stage amplifier 5 and the bypass final-stage amplifier 43 are fabricated on the gallium arsenide substrate. Amongst the driver-stage amplifier 3, the final-stage amplifier 5, the bypass driver-stage amplifier 42, and the bypass final-stage amplifier 43, it is the final-stage amplifier 5 and the bypass final-stage amplifier 43 that dominate the high-frequency characteristic of the module; the driver-stage amplifier 3 and the bypass driver-stage amplifier 42 do not particularly affect the high-frequency characteristic.

Hence, as long as the final-stage amplifier 5 and the bypass final-stage amplifier 43 are fabricated on the gallium arsenide substrate having the excellent high-frequency characteristic, the driver-stage amplifier 3 and the bypass driver-stage amplifier 42 may be fabricated on the silicon substrate 11 with a high-frequency characteristic comparable to that in the case where all components of the entire module are fabricated on the gallium arsenide substrate being maintained.

Fabricating the driver-stage amplifier 3 and the bypass driver-stage amplifier 42 on the silicon substrate 11 in the manner described above allows reducing the area of a chip made from a gallium arsenide substrate, thus decreasing the manufacturing cost.

In Embodiment 4, although the path changeover switches 44, 45, and 46 are fabricated on the silicon substrate 11, the path changeover switches 44, 45, and 46 may be fabricated on the gallium arsenide substrate.

In the Embodiment 4 above, the high-frequency amplifier module comprising the input matching circuit 2, the inter-stage matching circuit 4, and the output matching circuit 6 is shown. It is noted that all of the input matching circuit 2, the inter-stage matching circuit 4, and the output matching circuit 6 are optional, and that part or all of these circuits may be eliminated from the high-frequency amplifier module described above.

### Embodiment 5

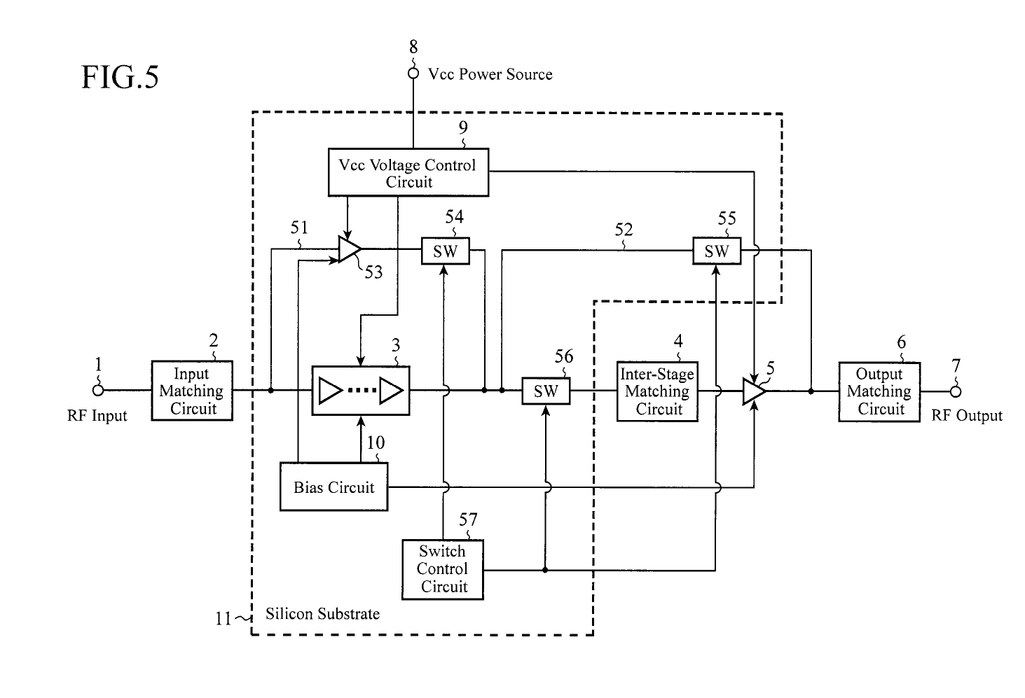

FIG. 5 is a configuration diagram showing a high-frequency amplifier module according to Embodiment 5 of the present invention. In the drawing, the same reference numerals as shown in FIG. 1 denote the same or equivalent parts. Redundant descriptions will be omitted.

A first bypass path 51 is a path that has two ends. One end of the two is connected to the input side of the driver-stage amplifier 3, and the other end is connected to the output side of the driver-stage amplifier 3.

A second bypass path 52 is a path that has two ends. One end of the two is connected to the input side of the final-stage amplifier 5, and the other end is connected to the output side of the final-stage amplifier 5.

In Embodiment 5, a path on which the driver-stage amplifier 3 and the final-stage amplifier 5 are arranged is referred to as a “main path.”

A bypass amplifier 53 is a driver-stage amplifier arranged in the first bypass path 51. The bypass amplifier 53 is designed to have a size smaller than that of the driver-stage amplifier 3.

A path changeover switch 54 is a switch arranged in the first bypass path 51 and on the output side of the bypass amplifier 53. The path changeover switch 54 is turned on or turned off under the control of a switch control circuit 57.

A path changeover switch 55 is a switch arranged in the second bypass path 52, and it is also turned on or turned off under the control of a switch control circuit 57.

A path changeover switch 56 is a switch arranged in the main path and on the output side of the driver-stage amplifier. The path changeover switch 56 is also turned on or turned off under the control of the switch control circuit 57.

The switch control circuit 57 is a circuit that turns ON/OFF the path changeover switches 54, 55, and 56 to select the main path or both or either of the bypass paths 51 and 52 as a path that allows the RF signal to flow therethrough.

In Embodiment 5, the bypass amplifier 53, the path changeover switches 54, 55, and 56 and the switch control circuit 57 are fabricated on the silicon substrate 11.

Next, the operation will be described.

First, upon receipt of the power source voltage Vcc supplied from the Vcc power source 8, the Vcc voltage control circuit 9 controls the DC voltage for the drain or collector of each of the driver-stage amplifier 3, the final-stage amplifier 5, and the bypass amplifier 53 to set the driver-stage amplifier 3, the final-stage amplifier 5, and the bypass amplifier 53 into a drivable state.

In order to set parameter values, such as an amplification factor of the RF signal in the driver-stage amplifier 3, the final-stage amplifier 5, and the bypass amplifier 53, to desired values, the bias circuit 10 provides a bias to the driver-stage amplifier 3, the final-stage amplifier 5, and the bypass amplifier 53 by controlling the DC voltage or DC current supplied to each gate or base of the driver-stage amplifier 3, the final-stage amplifier 5, and the bypass amplifier 53, for example, in accordance with information about settings of the amplification factor supplied from the outside.

When an RF signal is input from the RF input terminal 1 under a state in which the bias to the driver-stage amplifier 3, the final-stage amplifier 5, and the bypass amplifier 53 has been set by the bias circuit 10, the RF signal passes through the input matching circuit 2.

When the switch control circuit 57 receives, for example, control information directing that the RF signal should be driven with a low output power from the outside, the switch control circuit 57 selects the first and second bypass paths 51, 52 as paths for allowing the RF signal to flow by controlling the path changeover switches 54 and 55 to turn on and controlling the path changeover switch 56 to turn off.

As a result, the RF signal that has passed through the input matching circuit 2 is input to the bypass amplifier 53.

The bypass amplifier 53 amplifies the RF signal that has passed through the input matching circuit 2 and outputs the amplified RF signal.

The RF signal output from the bypass amplifier 53 is input to the output matching circuit 6 via the second bypass path 52.

The RF signal output from the bypass amplifier 22 passes through the output matching circuit 6 to be output to the outside from the RF output terminal 7.

When the switch control circuit 57 receives, for example, control information directing that the RF signal should be driven with a intermediate output power from the outside, the switch control circuit 57 selects the main path and the second bypass path 52 as paths for allowing the RF signal to flow by controlling the path changeover switches 54 and 56 to turn off and controlling the path changeover switch 55 to turn on.

As a result, the RF signal that has passed through the input matching circuit 2 is input to the driver-stage amplifier 3.

The driver-stage amplifier 3 amplifies the RF signal that has passed through the input matching circuit 2 and outputs the amplified RF signal.

The RF signal output from the driver-stage amplifier 3 is input to the output matching circuit 6 via the second bypass path 52.

The RF signal output from the driver-stage amplifier 3 passes through the output matching circuit 6 to be output to the outside from the RF output terminal 7.

When the switch control circuit 57 receives, for example, control information directing that the RF signal should be driven with a high output power from the outside, the switch control circuit 57 selects the main path as a path for allowing the RF signal to flow by controlling the path changeover switches 54 and 54 to turn off and controlling the path changeover switch 56 to turn on.

As a result, the RF signal that has passed through the input matching circuit 2 is input to the driver-stage amplifier 3.

The driver-stage amplifier 3 amplifies the RF signal that has passed through the input matching circuit 2 and outputs the amplified RF signal to the inter-stage matching circuit 4.

The RF signal output from the driver-stage amplifier 3 passes through the inter-stage matching circuit 4 to be input to the final-stage amplifier 5.

The final-stage amplifier 5 amplifies the RF signal that has passed through the inter-stage matching circuit 4 and outputs the amplified RF signal to the output matching circuit 6.

The RF signal output from the final-stage amplifier 5 passes through the output matching circuit 6 to be output to the outside from the RF output terminal 7.

In the high-frequency amplifier module illustrated in FIG. 5, the driver-stage amplifier 3 and the bypass amplifier 53 are fabricated on the silicon substrate 11, and the final-stage amplifier 5 is fabricated on the gallium arsenide substrate. Amongst the driver-stage amplifier 3, the final-stage amplifier 5, and the bypass amplifier 53, it is the final-stage amplifier 5 that dominates the high-frequency characteristic of the module; the driver-stage amplifier 3 and the bypass amplifier 53 do not particularly affect the high-frequency characteristic.

Hence, as long as the final-stage amplifier 5 is fabricated on the gallium arsenide substrate having the excellent high-frequency characteristic, the driver-stage amplifier 3 and the bypass amplifier 53 may be fabricated on the silicon substrate 11 with a high-frequency characteristic comparable to that in the case where all components of the entire module are fabricated on the gallium arsenide substrate being maintained.

Fabricating the driver-stage amplifier 3 and the bypass amplifier 53 on the silicon substrate 11 in the manner described above allows reducing the area of a chip made from a gallium arsenide substrate, thus decreasing the manufacturing cost.

In Embodiment 5, although the path changeover switches 54, 55, and 56 are fabricated on the silicon substrate 11, the path changeover switches 54, 55, and 56 may be fabricated on the gallium arsenide substrate.

In the Embodiment 5 above, the high-frequency amplifier module comprising the input matching circuit 2, the inter-stage matching circuit 4, and the output matching circuit 6 is shown. It is noted that all of the input matching circuit 2, the inter-stage matching circuit 4, and the output matching circuit 6 are optional, and that part or all of these circuits may be eliminated from the high-frequency amplifier module described above.

### Embodiment 6

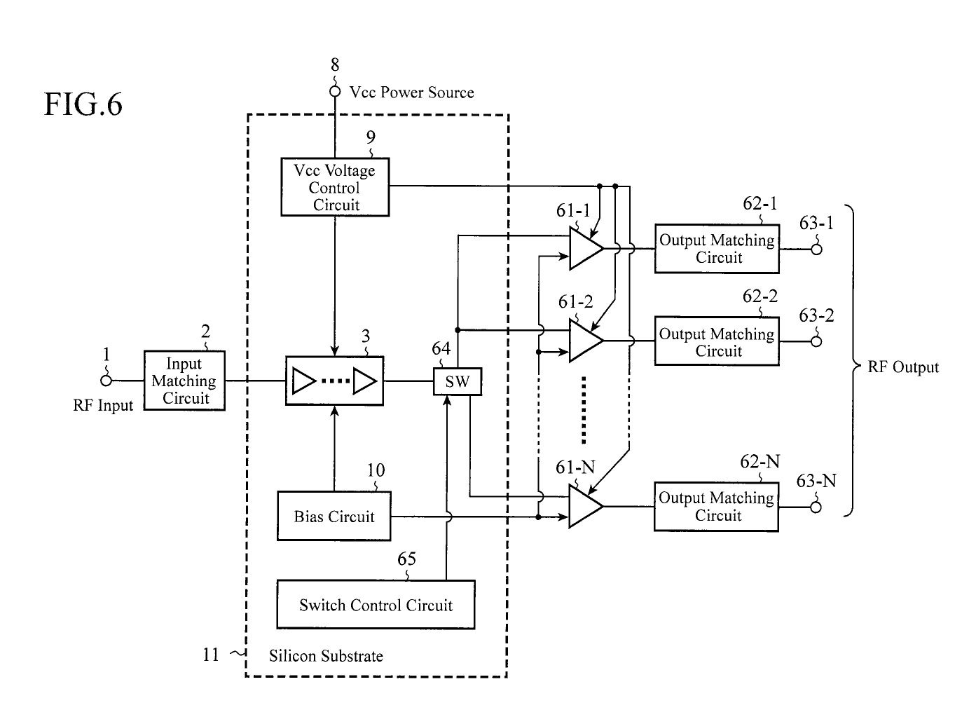

FIG. 6 is a configuration diagram showing a high-frequency amplifier module according to Embodiment 6 of the present invention. In the drawing, the same reference numerals as shown in FIG. 1 denote the same or equivalent parts. Redundant descriptions will be omitted.

Final-stage amplifiers 61-1 to 61-N are devices that are connected to the output side of the driver-stage amplifier 3 in parallel to each other. Each of the final-stage amplifiers 61-1 to 61-N further amplifies the RF signal amplified by the driver-stage amplifier 3 and outputs the further amplified RF signal to a corresponding output matching circuit 62-1 to 62-N.

The output matching circuits 62-1 to 62-N are matching circuits on the output side of the final-stage amplifiers 61-1 to 61-N.

RF output terminals 63-1 to 63-N are terminals that output the RF signal amplified by the final-stage amplifiers 61-1 to 61-N.

A path changeover switch 64 is a switch that outputs the RF signal amplified by the driver-stage amplifier 3 to one of the final-stage amplifiers 61 under the control of a switch control circuit 65.

The switch control circuit 65 is a circuit that changes the destination of an output from the path changeover switch 64.

In Embodiment 6, the driver-stage amplifier 3, the Vcc voltage control circuit 9, the bias circuit 10, the path changeover switch 64, and the switch control circuit 65 are fabricated on the silicon substrate 11.

The input matching circuit 2, the output matching circuits 62-1 to 62-N, and the final-stage amplifiers 61-1 to 61-N are fabricated on the gallium arsenide substrate.

Next, the operation will be described.

First, upon receipt of the power source voltage Vcc supplied from the Vcc power source 8, the Vcc voltage control circuit 9 controls the DC voltage for the drain or collector of each of the driver-stage amplifier 3 and the final-stage amplifiers 61-1 to 61-N to set the driver-stage amplifier 3 and the final-stage amplifiers 61-1 to 61-N into a drivable state.

In order to set parameter values, such as an amplification factor of the RF signal in the driver-stage amplifier 3 and the final-stage amplifiers 61-1 to 61-N, to desired values, the bias circuit 10 provides a bias to the driver-stage amplifier 3 and the final-stage amplifiers 61-1 to 61-N by controlling the DC voltage or DC current supplied to each gate or base of the driver-stage amplifier 3 and the final-stage amplifiers 61-1 to 61-N, for example, in accordance with information about settings of the amplification factor supplied from the outside.

When an RF signal is input from the RF input terminal 1 under a state in which the bias to the driver-stage amplifier 3 and the final-stage amplifiers 61-1 to 61-N has been set by the bias circuit 10, the RF signal passes through the input matching circuit 2.

In Embodiment 6, it is assumed that RF signals having different frequencies are successively input from the RF input terminal 1.

When the switch control circuit 65 receives, for example, information indicating the frequency of an RF signal from the outside, the switch control circuit 65 changes the destination of output from the path changeover switch 64 to a final-stage amplifier 61 corresponding to the frequency of the RF signal, thereby inputting the RF signal to a corresponding final-stage amplifier 61.

For example, the destination of output from the path changeover switch 64 is switched in such manner that: when the frequency of the RF signal is A Hz, the destination of output from the path changeover switch 64 is the final-stage amplifier 61-1; when the frequency of the RF signal is B Hz, the destination of output from the path changeover switch 64 is the final-stage amplifier 61-2; and when the frequency of the RF signal is C Hz, the destination of output from the path changeover switch 64 is the final-stage amplifier 61-N.

Out of the final-stage amplifiers 61-1 to 61-N, a final-stage amplifier 61 to which the RF signal has been input from the driver-stage amplifier 3 via the path changeover switch 64 amplifies the RF signal and outputs the amplified RF signal to a corresponding output matching circuit 62.

The RF signal output from one of the final-stage amplifiers 61-1 to 61-N passes through a corresponding output matching circuit 62-1 to 62-N to be output to the outside from a corresponding RF output terminal 63-1 to 63-N.

In the high-frequency amplifier module illustrated in FIG. 6, the driver-stage amplifier 3 is fabricated on the silicon substrate 11, and the final-stage amplifiers 61-1 to 61-N are fabricated on the gallium arsenide substrate. Amongst the driver-stage amplifier 3 and the final-stage amplifiers 61-1 to 61-N, it is the final-stage amplifiers 61-1 to 61-N that dominate the high-frequency characteristic of the module; the driver-stage amplifier 3 does not particularly affect the high-frequency characteristic.

Hence, as long as the final-stage amplifiers 61-1 to 61-N are fabricated on the gallium arsenide substrate having the excellent high-frequency characteristic, the driver-stage amplifier 3 may be fabricated on the silicon substrate 11 with a high-frequency characteristic comparable to that in the case where all components of the entire module are fabricated on the gallium arsenide substrate being maintained.

Fabricating the driver-stage amplifier 3 on the silicon substrate 11 in the manner described above allows reducing the area of a chip made from a gallium arsenide substrate, thus decreasing the manufacturing cost.

Note that, in Embodiment 6, although the path changeover switch 64 is fabricated on the silicon substrate 11, the path changeover switch 64 may be fabricated on the gallium arsenide substrate.

In Embodiment 6, a high-frequency amplifier module comprising the input matching circuit 2 and the final-stage amplifiers 61-1 to 61-N is illustrated. However, part or all of the input matching circuit 2 and the final-stage amplifiers 61-1 to 61-N may be omitted.

The high-frequency amplifier module may comprise an inter-stage matching circuit.

### Embodiment 7

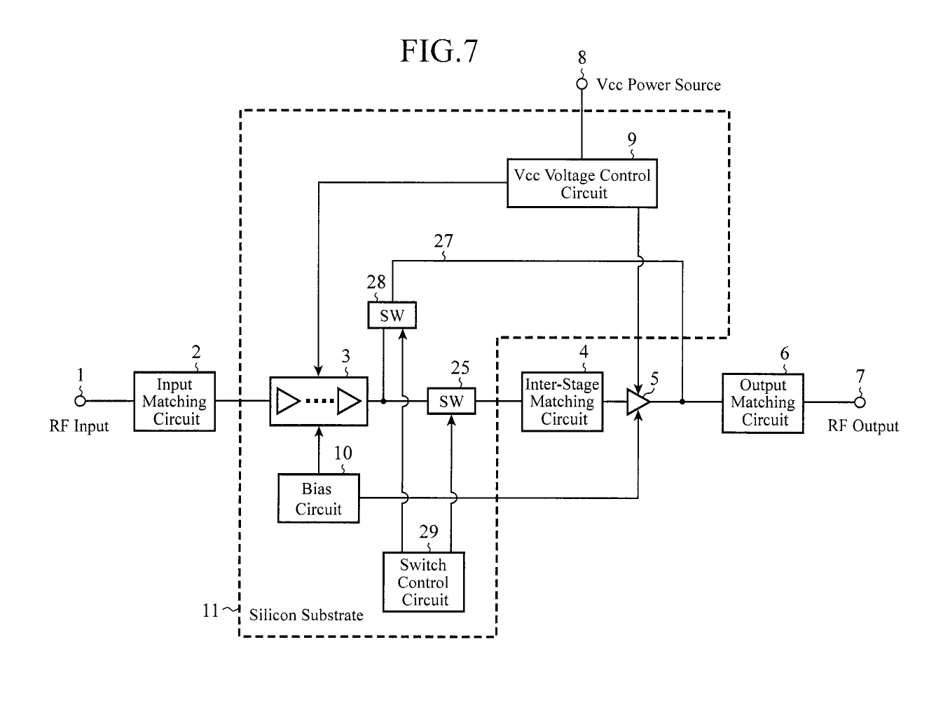

FIG. 7 is a configuration diagram showing a high-frequency amplifier module according to Embodiment 7 of the present invention. In the drawing, the same reference numerals as shown in FIG. 2 denote the same or equivalent parts. Redundant descriptions will be omitted.

A bypass path 27 is a path that has two ends. One end of the two is connected to the output side of the driver-stage amplifier 3, and the other end is connected to the output side of the driver-stage amplifier 5.

In Embodiment 7, a path in which the driver-stage amplifier 3 and the final-stage amplifier 5 are arranged is referred to as a “main path.”

In the bypass path 27A path arranged is a changeover switch 28, which is turned on or turned off under the control of a switch control circuit 29.

The switch control circuit 29 is a circuit that turns ON/OFF the path changeover switches 25 and 28 to select the main path or the bypass path 27 as a path that allows the RF signal to flow therethrough.

In Embodiment 7, the path changeover switches 25, 28 and the switch control circuit 29 are fabricated on the silicon substrate 11.

Next, the operation will be described.

First, upon receipt of the power source voltage Vcc supplied from the Vcc power source 8, the Vcc voltage control circuit 9 controls the DC voltage for the drain or collector of each of the driver-stage amplifier 3 and the final-stage amplifier 5 to set the driver-stage amplifier 3 and the final-stage amplifier 5 into a drivable state.

In order to set parameter values, such as an amplification factor of an RF signal in the driver-stage amplifier 3 and the final-stage amplifier 5, to desired values, the bias circuit 10 provides a bias to the driver-stage amplifier 3 and the final-stage amplifier 5 by controlling the DC voltage or DC current supplied to each gate or base of the driver-stage amplifier 3 and the final-stage amplifier 5, for example, in accordance with information about settings of the amplification factor supplied from the outside.

When an RF signal is input from the RF input terminal 1 under a state in which the bias to the driver-stage amplifier 3 and the final-stage amplifier 5 has been set by the bias circuit 10, the RF signal goes through the input matching circuit 2.

When the switch control circuit 29 receives, for example, control information directing that the RF signal should be driven with a low output power from the outside, the switch control circuit 29 selects the bypass path 27 as a path for allowing the RF signal to flow by controlling the path changeover switch 28 to turn on and controlling the path changeover switch 25 to turn off.

As a result, the RF signal that has passed through the input matching circuit 2 is input to the output matching circuit 6 via the bypass path 27.

The RF signal output from the bypass path 27 passes through the output matching circuit 6 to be output to the outside from the RF output terminal 7.

When the switch control circuit 29 receives, for example, control information directing that the RF signal should be driven with a high output power from the outside, the switch control circuit 29 selects the main path as a path for allowing the RF signal to flow by controlling the path changeover switches 28 to turn off and controlling the path changeover switch 25 to turn on.

As a result, the RF signal that has passed through the input matching circuit 2 is input to the driver-stage amplifier 3.

The driver-stage amplifier 3 amplifies the RF signal that has passed through the input matching circuit 2 and outputs the amplified RF signal to the inter-stage matching circuit 4.

The RF signal output from the driver-stage amplifier 3 passes through the inter-stage matching circuit 4 to be input to the final-stage amplifier 5.

The final-stage amplifier 5 amplifies the RF signal that has passed through the inter-stage matching circuit 4 and outputs the amplified RF signal to the output matching circuit 6.

The RF signal output from the final-stage amplifier 5 passes through the output matching circuit 6 to be output to the outside from the RF output terminal 7.

In the high-frequency amplifier module illustrated in FIG. 7, the driver-stage amplifier 3 is fabricated on the silicon substrate 11, and the final-stage amplifier 5 is fabricated on the gallium arsenide substrate. Amongst the driver-stage amplifier 3 and the final-stage amplifier 5, it is the final-stage amplifier 5 that dominates the high-frequency characteristic of the module; the driver-stage amplifier 3 do not particularly affect the high-frequency characteristic.

Hence, as long as the final-stage amplifier 5 is fabricated on the gallium arsenide substrate having the excellent high-frequency characteristic, the driver-stage amplifier 3 may be fabricated on the silicon substrate 11 with a high-frequency characteristic comparable to that in the case where all components of the entire module are fabricated on the gallium arsenide substrate being maintained.

Fabricating the driver-stage amplifier 3 on the silicon substrate 11 in the manner described above allows reducing the area of a chip made from a gallium arsenide substrate, thus decreasing the manufacturing cost.

In Embodiment 7, although the path changeover switches 25 and 28 are fabricated on the silicon substrate 11, the path changeover switches 25 and 28 may be fabricated on the gallium arsenide substrate.

In the Embodiment 7 above, the high-frequency amplifier module comprising the input matching circuit 2, the inter-stage matching circuit 4, and the output matching circuit 6 is shown. It is noted that all of the input matching circuit 2, the inter-stage matching circuit 4, and the output matching circuit 6 are optional, and that part or all of these circuits may be eliminated from the high-frequency amplifier module described above.

### Embodiment 8

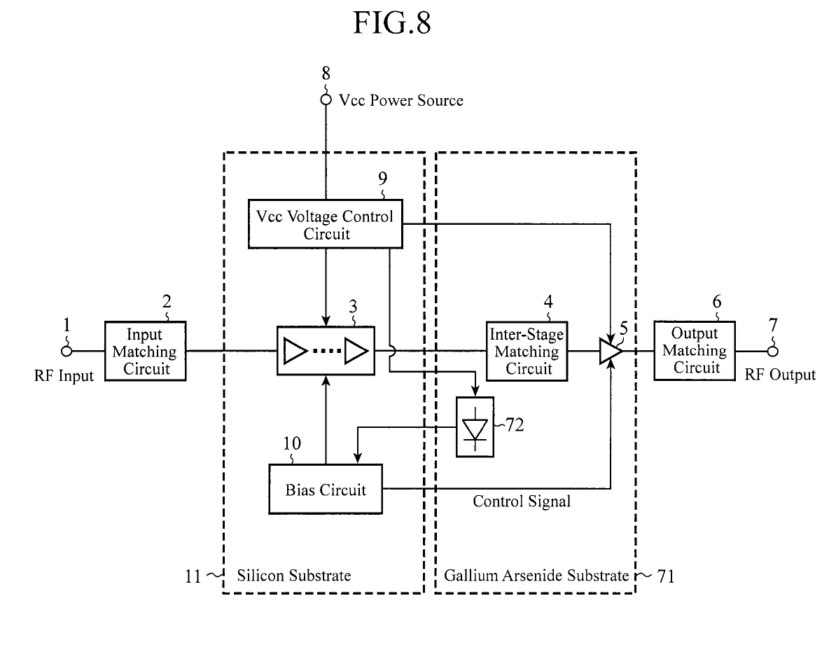

FIG. 8 is a configuration diagram showing a high-frequency amplifier module according to Embodiment 8 of the present invention. In the drawing, the same reference numerals as shown in FIG. 2 denote the same or equivalent parts. Redundant descriptions will be omitted.

A gallium arsenide substrate 71 is a substrate made from gallium arsenide, on which the inter-stage matching circuit 4, the final-stage amplifier 5, and a temperature sensing circuit 72 are fabricated.

The temperature sensing circuit 72 senses the temperature of the gallium arsenide substrate 71 and adjusts the bias that is set by the bias circuit 10 in accordance with the temperature of the gallium arsenide substrate 71. Note that the temperature sensing circuit 72 forms a bias adjustment unit.

Next, the operation will be described.

Note that Embodiment 8 is the same as Embodiment 1 described above except that the temperature sensing circuit 72 is fabricated, and that the operation will be described mainly about the processing of the temperature sensing circuit 72.

In order to set parameter values, such as an amplification factor of an RF signal in the driver-stage amplifier 3 and the final-stage amplifier 5, to desired values, the bias circuit 10 provides a bias to the driver-stage amplifier 3 and the final-stage amplifier 5 by controlling the DC voltage or DC current supplied to each gate or base of the driver-stage amplifier 3 and the final-stage amplifier 5, for example, in accordance with information about settings of the amplification factor supplied from the outside, in the same manner as in Embodiment 1 described above.

Here, the temperature sensing circuit 72 has a function of sensing the temperature of the gallium arsenide substrate 71 and senses a temperature T of the gallium arsenide substrate 71.

For example, the temperature sensing circuit 72 is able to sense the temperature of the gallium arsenide substrate 71 by being constructed with a diode or a bipolar transistor having substantially the same temperature characteristic as that of the gallium arsenide substrate 71.

On sensing the temperature T of the gallium arsenide substrate 71, the temperature sensing circuit 72 calculates a difference ΔT between the temperature T of the gallium arsenide substrate 71 and a reference temperature Tref set in advance and outputs an adjustment signal corresponding to the difference ΔT to the bias circuit 10:

ΔT=T−Tref.

On receiving the adjustment signal corresponding to the difference ΔT from the temperature sensing circuit 72, the bias circuit 10 adjusts a control signal (a control voltage for controlling the DC voltage or DC current to be supplied to the gate or base of the driver-stage amplifier 3 and the final-stage amplifier 5) to the driver-stage amplifier 3 and the final-stage amplifier 5 in accordance with the adjustment signal. For example, in the case where the temperature T of the gallium arsenide substrate 71 is higher than the reference temperature Tref, the control voltage is adjusted in such manner that the control voltage gets smaller as the absolute value of the difference ΔT gets larger.

Conversely, in the case where the temperature T of the gallium arsenide substrate 71 is lower than the reference temperature Tref, the control voltage is adjusted in such manner that the control voltage gets larger as the absolute value of the difference ΔT gets larger.

By this, a bias can be supplied with the temperature variation being compensated.

In the high-frequency amplifier module illustrated in FIG. 8, the driver-stage amplifier 3 is fabricated on the silicon substrate 11, and the final-stage amplifier 5 is fabricated on the gallium arsenide substrate 71. Amongst the driver-stage amplifier 3 and the final-stage amplifier 5, it is the final-stage amplifier 5 that dominates the high-frequency characteristic of the module; the driver-stage amplifier 3 does not particularly affect the high-frequency characteristic.

Hence, as long as the final-stage amplifier 5 is fabricated on the gallium arsenide substrate 71 having an excellent high-frequency characteristic, the driver-stage amplifier 3 may be fabricated on the silicon substrate 11 with a high-frequency characteristic that is comparable to that in the case where all components of an entire module are fabricated on a gallium arsenide substrate being maintained.

In addition, the temperature sensing circuit 72, which senses the temperature of the gallium arsenide substrate 71 to adjust the bias set by the bias circuit 10 in accordance with the temperature of the gallium arsenide substrate 71, is fabricated on the gallium arsenide substrate 71. Therefore, although the bias circuit 10 is fabricated on the silicon substrate 11, a high-frequency amplifier module capable of temperature compensation can be obtained.

In this case, since the bias circuit 10 need not be fabricated on the gallium arsenide substrate 71, it is possible to reduce the area of the chip formed of the gallium arsenide substrate 71. Therefore, it is possible to achieve lower cost for the high-frequency amplifier module capable of temperature compensation.

### Embodiment 9

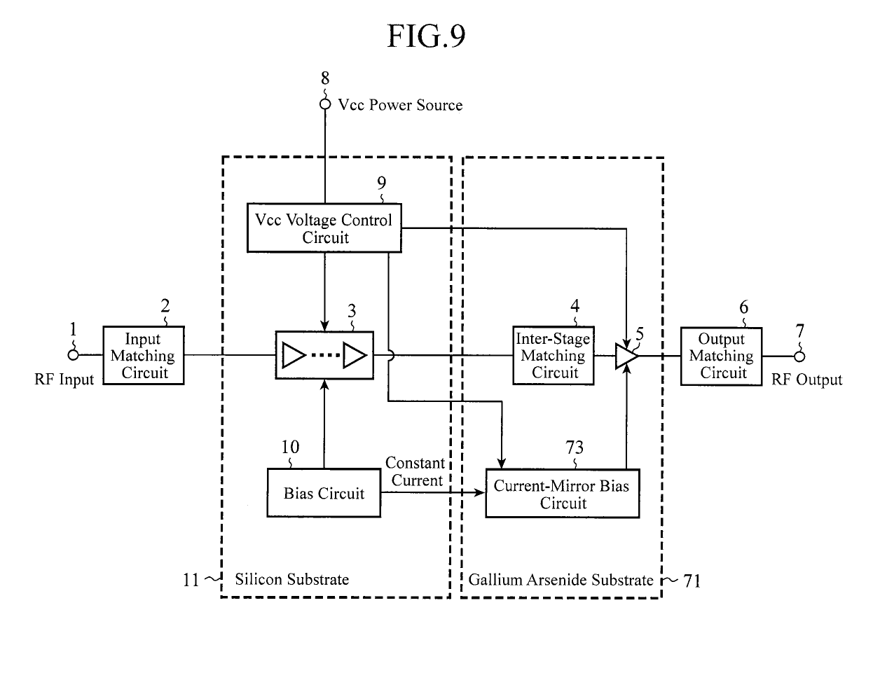

FIG. 9 is a configuration diagram showing a high-frequency amplifier module according to Embodiment 9 of the present invention. In the drawing, the same reference numerals as shown in FIG. 2 denote the same or equivalent parts. Redundant descriptions will be omitted.

A current-mirror bias circuit 73 is a circuit fabricated on the gallium arsenide substrate 71 to form a current mirror with a constant-current control signal output from the bias circuit 10, and constitutes a bias adjustment unit that adjusts the bias that is set by the bias circuit 10.

Note that the same device as the final-stage transistor 5 is used as a transistor for current mirror in the current-mirror bias circuit 73.

In the high-frequency amplifier module illustrated in FIG. 9, the current-mirror bias circuit 73 fabricated on the gallium arsenide substrate 71 forms the current mirror with the constant-current control signal output from the bias circuit 10.

Accordingly, as long as the transistor for current-mirror included in the current-mirror bias circuit 73 is constructed with the same device as the final-stage transistor 5, the control signal as the output signal from the bias circuit 10 is adjusted by the current-mirror bias circuit 73 in accordance with the temperature of the gallium arsenide substrate 71, and the control signal after the temperature adjustment is fed thereby to the final-stage amplifier 5.

Note that, in Embodiment 2 described above, the control signal as the output signal from the bias circuit 10 fabricated on the silicon substrate 11 is directly fed to the final-stage amplifier 5 fabricated on the gallium arsenide substrate 71.

By this, a bias can be supplied with the temperature variation being compensated.

In the high-frequency amplifier module illustrated in FIG. 9, the driver-stage amplifier 3 is fabricated on the silicon substrate 11, and the final-stage amplifier 5 is fabricated on the gallium arsenide substrate 71. Amongst the driver-stage amplifier 3 and the final-stage amplifier 5, it is the final-stage amplifier 5 that dominates the high-frequency characteristic of the module; the driver-stage amplifier 3 does not particularly affect the high-frequency characteristic.

Hence, as long as the final-stage amplifier 5 is fabricated on the gallium arsenide substrate 71 having an excellent high-frequency characteristic, the driver-stage amplifier 3 may be fabricated on the silicon substrate 11 with a high-frequency characteristic that is comparable to that in the case where all components of an entire module are fabricated on a gallium arsenide substrate being maintained.

Moreover, the current-mirror bias circuit 73, which forms the current mirror with the constant-current control signal output from the bias circuit 10, is fabricated on the gallium arsenide substrate 71. Therefore, although the bias circuit 10 is fabricated on the silicon substrate 11, the high-frequency amplifier module capable of temperature compensation can be obtained.

In this case, since the bias circuit 10 need not be fabricated on the gallium arsenide substrate 71, it is possible to reduce the area of the chip formed of the gallium arsenide substrate 71. Therefore, it is possible to achieve lower cost for the high-frequency amplifier module capable of temperature compensation.

In Embodiment 9, the high-frequency amplifier module in which the current-mirror bias circuit 73 that forms a current mirror with the constant-current control signal output from the bias circuit 10 is fabricated on the gallium arsenide substrate 71 is shown. However, instead of the current-mirror bias circuit 73, an emitter-follower bias circuit including a bipolar transistor constructed with the same device as that of the final-stage transistor 5 may also be fabricated on the gallium arsenide substrate 71.

In this case, the current-voltage control signal as the output signal from the bias circuit 10 is adjusted by the emitter-follower bias circuit in accordance with the temperature of the gallium arsenide substrate 71, and the control signal after the temperature adjustment is fed thereby to the final-stage amplifier 5.

As a result, in a similar manner to that in the case where the current-mirror bias circuit 73 is fabricated on the gallium arsenide substrate 71, a bias can be supplied with the temperature variation being compensated. Therefore, it is possible to achieve lower cost for the high-frequency amplifier module capable of temperature compensation.

### Embodiment 10

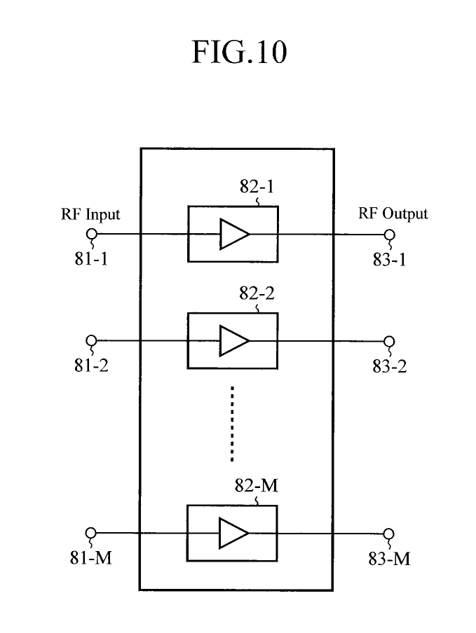

FIG. 10 is a configuration diagram showing a high-frequency amplifier module unit according to Embodiment 10 of the present invention.

In FIG. 10, RF input terminals 81-1 to 81-M are terminals to which RF signals are input.

In Embodiment 10, it is assumed that RF signals having different frequencies are input from the RF input terminals 81-1 to 81-M.

Each of high-frequency amplifier modules 82-1 to 82-M are any one of high-frequency amplifier modules (high-frequency amplifier modules each shown in any of FIGS. 1 to 5 and 7 to 9) described in Embodiments 1 to 5 and 7 to 9 above. The RF signals amplified by the high-frequency amplifier modules 82-1 to 82-M are output from RF output terminals 83-1 to 83-M.

Even when the high-frequency amplifier module unit is constructed in which a plurality of high-frequency amplifier modules are packaged, by arranging the high-frequency amplifier modules 82-1 to 82-M that are formed of the silicon substrate and the gallium arsenide substrate in the manner shown in FIG. 10, a cost reduction can be achieved maintaining an excellent high-frequency characteristic in a similar way to Embodiments 1 to 5 and 7 to 9 described above.

### Embodiment 11

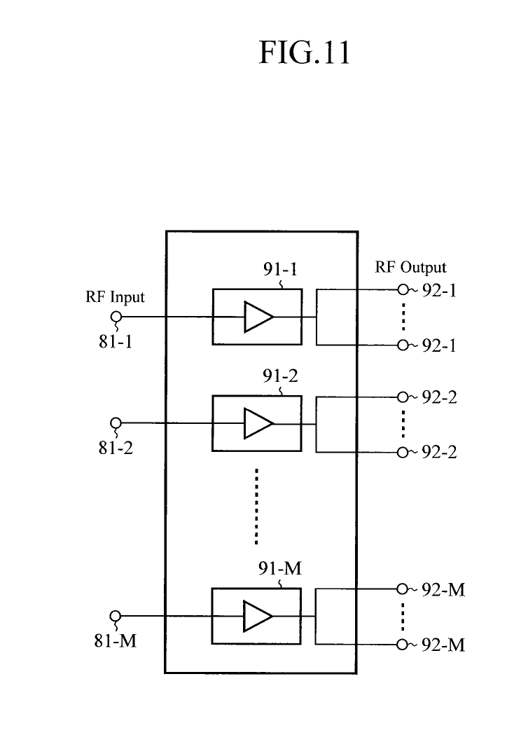

FIG. 11 is a configuration diagram showing a high-frequency amplifier module unit according to Embodiment 11 of the present invention. In the drawing, the same reference numerals as shown in FIG. 10 denote the same or equivalent parts. Redundant descriptions will be omitted.

Each of high-frequency amplifier modules 91-1 to 91-M is the high-frequency amplifier module (high-frequency amplifier module shown in FIG. 6) described in Embodiment 6 above. The RF signals amplified by the high-frequency amplifier modules 91-1 to 91-M are output from RF output terminals 92-1 to 92-M.

Even when the high-frequency amplifier module unit is constructed in which a plurality of high-frequency amplifier modules are packaged, by arranging the high-frequency amplifier modules 91-1 to 91-M that are formed of the silicon substrate and the gallium arsenide substrate in the manner shown in FIG. 10, a cost reduction can be achieved maintaining an excellent high-frequency characteristic in a similar way to Embodiment 6 described above.

Note that, within the scope of the present invention, the embodiments described above may be combined in any manner or components in the embodiments may be modified or omitted.

### INDUSTRIAL APPLICABILITY

The present invention is appropriate, in amplifying an RF signal that is a high-frequency signal, for example for a high-frequency amplifier module that needs to be manufactured at low cost maintaining a high-frequency characteristic comparable to that in the case where the entire module is fabricated on a gallium arsenic substrate.

### EXPLANATION OF REFERENCE NUMERALS

1 RF input terminal
2 input matching circuit
3 driver-stage amplifier
4 inter-stage matching circuit
5 final-stage amplifier
6 output matching circuit
7 RF output terminal
8 Vcc power source
9 Vcc voltage control circuit (power source voltage control circuit)
10 bias circuit
11 silicon substrate
21, 27, 31, and 41 bypass paths
22 and 32 bypass amplifiers
23, 24, 25, 28, 33, 34, 35, 44, 45, and 46 path changeover switches
26, 29, 36, and 47 switch control circuits
42 bypass driver-stage amplifier
43 bypass final-stage amplifier
51 first bypass path
52 second bypass path
53 bypass amplifier
54, 55, and 56 path changeover switches
57 switch control circuit
61-1 to 61-N final-stage amplifiers
62-1 to 62-N output matching circuits
63-1 to 63-N RF output terminals
64 path changeover switch
65 switch control circuit
71 gallium arsenide substrate
72 temperature sensing circuit (bias adjustment unit)
73 current-mirror bias circuit (bias adjustment unit)
81-1 to 81-M RF input terminals
82-1 to 82-M high-frequency amplifier modules
83-1 to 83-M RF output terminals
91-1 to 91-M high-frequency amplifier modules
92-1 to 92-M RF output terminals
101 RF input terminal
102 driver-stage amplifier
103 final-stage amplifier
104 RF output terminal
105 bypass path
106 switch control circuit
107 and 108 changeover switches
109 Vcc power source
110 bias circuit

1. A high-frequency amplifier module, comprising:
a silicon substrate;
a gallium arsenide substrate;
a driver-stage amplifier that includes a plurality of amplifiers arranged in multi-stages and amplifies a signal input from an input terminal;
a final-stage amplifier that further amplifies the amplified signal amplified by the driver-stage amplifier and outputs the further amplified signal to an output terminal;
a bypass path with an end being connected to an input side of the driver-stage amplifier and another end being connected to an output side of the final-stage amplifier; and
a bypass amplifier that is arranged in the bypass path, wherein
the driver-stage amplifier is fabricated on the silicon substrate, and the final-stage amplifier is fabricated on the gallium arsenide substrate, and
at least part of the bypass amplifier is fabricated on the silicon substrate.

2. (canceled)

3. The high-frequency amplifier module according to claim 1,
wherein the bypass amplifier has a size smaller than that of the final-stage amplifier.

4. The high-frequency amplifier module according to claim 1, further comprising:
a bypass driver-stage amplifier that includes a plurality of amplifiers arranged in multi-stages and amplifies a signal input from the input terminal; and
a bypass final-stage amplifier that is arranged in the bypass path and further amplifies the signal amplified by the bypass driver-stage amplifier to output the further simplified signal to the output terminal, wherein
the bypass driver-stage amplifier is fabricated on the silicon substrate, and the bypass final-stage amplifier is fabricated on the gallium arsenide substrate.

5. The high-frequency amplifier module according to claim 1, further comprising:
a first bypass path with an end being connected to an input side of the driver-stage amplifier and another end being connected to an output side of the driver-stage amplifier;
a second bypass path with an end being connected to an input side of the final-stage amplifier and another end being connected to an output side of the final-stage amplifier; and
a bypass amplifier that is arranged in the first bypass path and has a size smaller than that of the driver-stage amplifier, wherein
the bypass amplifier is fabricated on the silicon substrate.

6. The high-frequency amplifier module according to claim 1, wherein there are a plurality of the final-stage amplifiers fabricated on the gallium arsenide substrate that are connected in parallel to each other to an output side of the driver-stage amplifier.

7. The high-frequency amplifier module according to claim 1, further comprising a bypass path with an end being connected to an output side of the driver-stage amplifier and another end being connected to an output side of the final-stage amplifier.

8. The high-frequency amplifier module according to claim 1, further comprising:
an input matching circuit is arranged on an input side of the driver-stage amplifier;
an inter-stage matching circuit arranged between the driver-stage amplifier and the final-stage amplifier; and
an output matching circuit arranged on an output side of the final-stage amplifier, wherein
part or all of the input matching circuit, the inter-stage matching circuit, and the output matching circuit are fabricated on the gallium arsenide substrate.

9. The high-frequency amplifier module according to claim 1, further comprising:
an input matching circuit is arranged on an input side of the driver-stage amplifier;
an inter-stage matching circuit arranged between the driver-stage amplifier and the final-stage amplifier; and
an output matching circuit arranged on an output side of the final-stage amplifier, wherein
part or all of the input matching circuit, the inter-stage matching circuit, and the output matching circuit are fabricated on the silicon substrate or on an external module.

10. The high-frequency amplifier module according to claim 1, further comprising a path changeover switch that selects, as a path which allows the signal to flow therethrough, one of a main path in which the driver-stage amplifier and the final-stage amplifier are arranged and the bypass path, wherein the path changeover switch is fabricated on the silicon substrate.

11. The high-frequency amplifier module according to claim 10, further comprising a switch control circuit that controls the path changeover switch, wherein the switch control circuit is fabricated on the silicon substrate.

12. The high-frequency amplifier module according to claim 6, further comprising a path changeover switch that selects, from among the plurality of final-stage amplifiers, a final-stage amplifier to which the signal amplified by the driver-stage amplifier is to be fed, wherein the path changeover switch is fabricated on the silicon substrate.

13. The high-frequency amplifier module according to claim 12, further comprising a switch control circuit that controls the path changeover switch, wherein the switch control circuit is fabricated on the silicon substrate.

14. The high-frequency amplifier module according to claim 1, further comprising a bias circuit that sets a bias to the driver-stage amplifier and the final-stage amplifier, wherein the bias circuit is fabricated on the silicon substrate.

15. The high-frequency amplifier module according to claim 1, further comprising a power source voltage control circuit that controls a power source voltage to the driver-stage amplifier and the final-stage amplifier, wherein the power source voltage control circuit is fabricated on the silicon substrate.

16. The high-frequency amplifier module according to claim 14, further comprising a bias adjustment unit that is fabricated on the gallium arsenide substrate and adjusts the bias set by the bias circuit.

17. The high-frequency amplifier module according to claim 16, wherein
the bias adjustment unit comprises a temperature sensing circuit that senses a temperature of the gallium arsenide substrate, and
the temperature sensing circuit adjusts the bias set by the bias circuit in accordance with the temperature of the gallium arsenide substrate.

18. The high-frequency amplifier module according to claim 16, wherein the bias adjustment unit comprises a current-mirror bias circuit including a bipolar transistor.

19. The high-frequency amplifier module according to claim 16, wherein the bias adjustment unit comprises an emitter-follower bias circuit including a bipolar transistor.

20. A high-frequency amplifier module unit that comprises a plurality of high-frequency amplifier modules according to claim 1.
